(19) United States
(12) Patent Application Publication
(10) Pub. No.: US 2019/0217426 A1
(43) Pub. Date: Jul. 18, 2019

(54) PORTABLE WELDING SYSTEM WITH A MAIN CASE HAVING MECHANICAL ATTACHMENTS MECHANISM FOR FACILITATING COUPLING

(71) Applicant: ESAB AB, Goteborg (SE)

(72) Inventor: Jeroen Dekker, Olofstorp (SE)

(21) Appl. No.: 16/244,458

(22) Filed: Jan. 10, 2019

Related U.S. Application Data
(63) Continuation of application No. PCT/EP2016/066760, filed on Jul. 14, 2016.

(51) Int. Cl. B23K 37/02; B23K 9/32; H05K 5/00; H05K 7/14; H05K 5/02

(52) U.S. Cl. CPC B23K 37/0294; B23K 9/323; H05K 5/0221; H05K 5/0021; H05K 7/1432; B23K 37/0205

(57) ABSTRACT

A portable welding system including a main case housing a primary welding device that facilitates a welding function of the portable welding apparatus, and a modular welding component removeably attached to a bottom of the portable welding apparatus, the modular welding component comprising a component case housing a secondary welding device that supplements the primary welding device.

### CROSS-REFERENCE TO RELATED APPLICATIONS

This application is a continuation of International Application No. PCT/EP2016/066760, filed on Jul. 14, 2016, the entire contents of which is hereby incorporated by reference.

### FIELD OF THE DISCLOSURE

The disclosure generally relates to welding equipment, and more particularly to a rugged, modular portable welding system.

### BACKGROUND OF THE DISCLOSURE

Portable welding systems are known, and often incorporate a welding power supply and related mechanisms (e.g., wire feeder, wire spool) in a portable case. Such portable welding systems find use in applications where it is not practical or convenient to send a work-piece to a shop for repair or fabrication. Examples of applications for such portable welding systems include petroleum and chemical fabrication, shipboard installation and repair, and the like. As such, known portable welding systems may be relatively light weight to enable a user to lift and carry the system to the work site. Because of the portability and flexibility of these welding systems they have found wide-spread use and popularity.

A problem commonly associated with portable welders is that they are often not sufficiently rugged to withstand harsh treatment that they may be subjected to during transport and use. Due to the nature of the environment in which portable welders are used, they may become damaged and may require repair at shorter than desired intervals. Another problem commonly associated with prior portable welders is that they are often difficult to grasp, lift, and/or carry by a user. This problem may be exacerbated when a portable welder includes multiple separate components.

It is with respect to these and other considerations that the present improvements may be useful.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

An exemplary embodiment of a portable welding apparatus in accordance with the present disclosure may include a main case housing a primary welding device that facilitates a welding function of the portable welding apparatus, the main case having a mechanical attachment mechanism on a bottom surface thereof for facilitating coupling of the portable welding apparatus to a component case of a modular welding component housing a secondary welding device that supplements the primary welding device.

An exemplary embodiment of a portable welding system in accordance with the present disclosure may include a main case housing a primary welding device that facilitates a welding function of the portable welding apparatus, and a modular welding component removeably attached to a bottom of the portable welding apparatus, the modular welding component comprising a component case housing a secondary welding device that supplements the primary welding device.

### BRIEF DESCRIPTION OF THE DRAWINGS

By way of example, a specific embodiment of the disclosed device will now be described, with reference to the accompanying drawings, in which:

FIG. 1 is a front perspective view illustrating an embodiment of a welding system in accordance with the present disclosure;

FIG. 2 is a perspective view illustrating an embodiment of a welding apparatus of the welding system shown in FIG. 1;

FIG. 3A is a front perspective view illustrating an embodiment of a modular welding component of the welding system shown in FIG. 1;

FIG. 3B is a rear perspective view illustrating an embodiment of the modular welding component shown in FIG. 3A;

FIGS. 4A-C are a series of perspective views illustrated the welding apparatus shown in FIG. 1 being coupled to a modular welding component;

FIGS. 5A-B are perspective views illustrating embodiments of welding systems coupled to a non-modular welding component;

FIG. 6A is another front perspective view illustrating the welding apparatus shown in FIG. 1;

FIG. 6B is a rear perspective view illustrating the welding apparatus shown in FIG. 6A;

FIG. 7 is a side view illustrating the welding apparatus shown in FIG. 6A;

FIG. 8 is a side cutaway view illustrating the welding apparatus shown in FIG. 6A;

FIG. 9A is a cross sectional view taken along plane A-A in FIG. 8;

FIG. 9B is a cross sectional view taken along plane B-B in FIG. 8;

FIG. 9C is a cross sectional view taken along plane C-C in FIG. 8;

FIG. 10 is a perspective view illustrating a modular welding component with a coolant supply;

FIG. 11 is a side view illustrating a reservoir for a coolant supply.

### DETAILED DESCRIPTION

The present embodiments will now be described more fully hereinafter with reference to the accompanying drawings, in which several exemplary embodiments are shown. The subject matter of the present disclosure, however, may be embodied in many different forms and should not be construed as limited to the embodiments set forth herein. Rather, these embodiments are provided so that this disclosure will be thorough and complete, and will fully convey the scope of the subject matter to those skilled in the art. In the drawings, like numbers refer to like elements throughout.

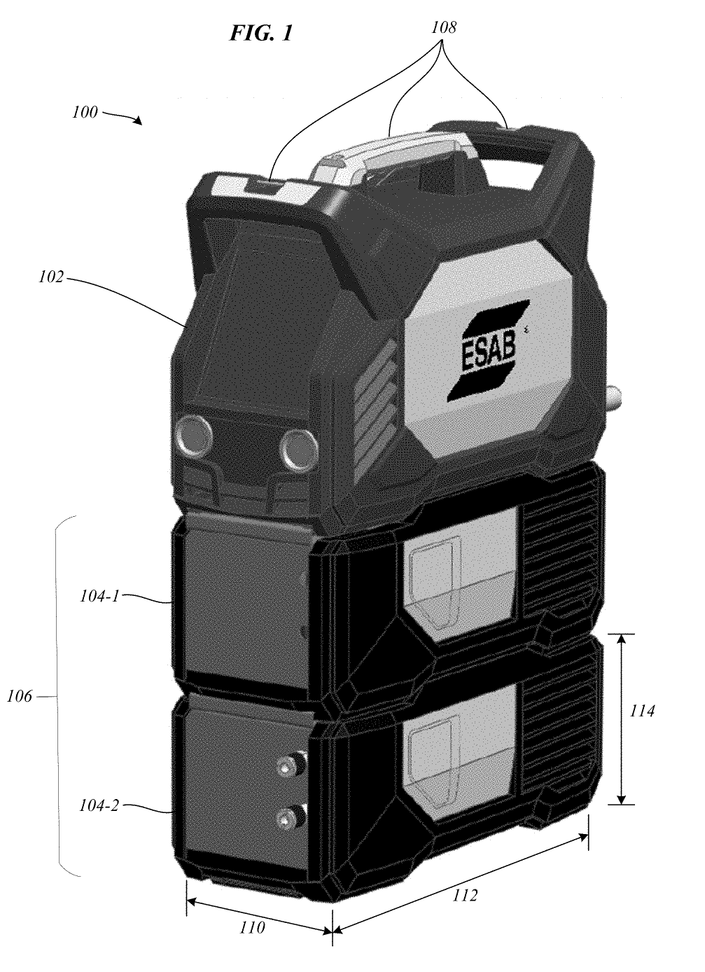

Referring to FIG. 1, a perspective view of a portable welding system 100 (hereinafter “the system 100”) consistent with a non-limiting, exemplary embodiment of the present disclosure is shown. The welding system 100 may include a welding apparatus 102 (hereinafter “the apparatus 102”) and one or more modular welding components, such as first and second modular welding components 104-1, 104-2. The apparatus 102 may be used to perform welding operations in remote locations. The modular welding components 104-1, 104-2 may be used in conjunction with the apparatus 102 to provide additional functionality and/or improve the welding capabilities of the system 100. For example, the modular welding component 104-1 may include an AC/DC power conditioner, while the modular welding component 104-2 may include a coolant supply. The embodiments are not limited in this context.

The welding apparatus 102 may couple to one or more of the modular welding components 104-1, 104-2 in a convenient manner as further described below to simplify transportation and improve flexibility of the system 100. In various embodiments, the modular welding component 104-1 may couple to one or more other modular welding components (e.g., 104-2) to form a modular welding component stack 106. In various such embodiments, the apparatus 102 may be coupled to the top of the stack 106. As may be appreciated, although the illustrated embodiment includes two modular welding components 104-1, 104-2, a greater or fewer number of modular welding components may be implemented in the system 100 without departing from the present disclosure.

As shown in FIG. 1, the apparatus 102 may include one or more lifting points 108. In some embodiments the lifting points 108 may be used independently or in combination to lift and support the apparatus 102 along with a stack 106 of attached modular welding components, thereby allowing the system 100 to be moved as a single unit instead of piece-by-piece, thus simplifying transport of the system 100. For example, a crane would only need to perform a single lift with elementary rigging to relocate the system 100 instead of requiring complex rigging or a separate lift for each piece of the system 100.

In some embodiments, one or more exterior dimensions of the welding apparatus 102 may approximately match corresponding dimensions of the modular welding components 104-1, 104-2. For example, the apparatus 102 and each of the modular welding components 104-1, 104-2 may have substantially the same width 110 and depth 112. As shown in FIG. 1, this uniformity may allow the apparatus 102 to be stacked on top of any number of modular welding components while maintaining a substantially consistent “footprint.” In other words, the welding apparatus 102 alone would take up approximately the same amount of floor space as when apparatus 102 is coupled to the stack 106. In various embodiments, each modular welding component 104-1, 104-2 may share a common set of exterior dimensions. For instance, the width 110, depth 112, and height 114 may be substantially the same for each of the modular welding components 104-1, 104-2. In various such embodiments, the overall exterior dimensions of the welding system 100 may be readily determined in advance of assembling the system 100, as long as the number of modular welding components to be utilized in the system 100 is known or determinable. These dimensional uniformities can enable the system 100 to take up less floor space as well as to fit through small openings (e.g., man holes, crawlspaces), thereby improving both the utility and the flexibility of the system 100 relative to conventional portable welders.

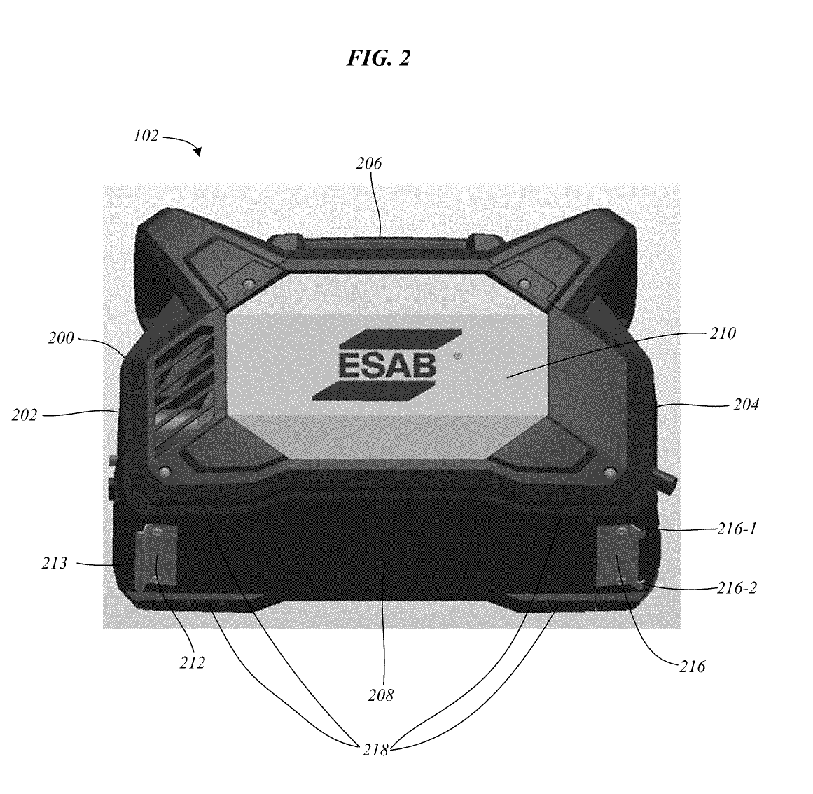

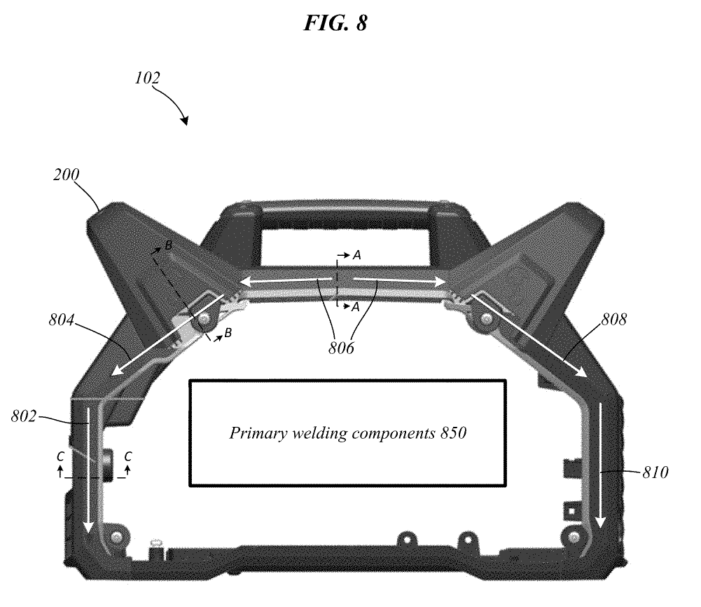

Referring to FIG. 2, a perspective bottom view of the welding apparatus 102 is shown. The welding apparatus 102 may include a main case 200. The main case 200 may enclose and protect one or more primary welding devices 850 (see, e.g., FIG. 8). The one or more primary welding devices 850 may operate to provide welding functionality to the apparatus 102. In some embodiments the welding functionality may include a tungsten inert gas (TIG) welding operation. The embodiments are not limited in this context.

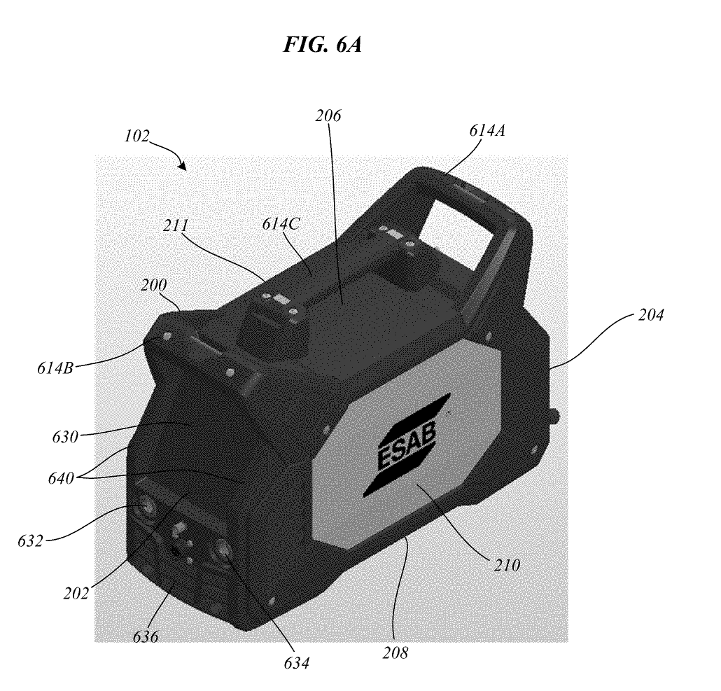

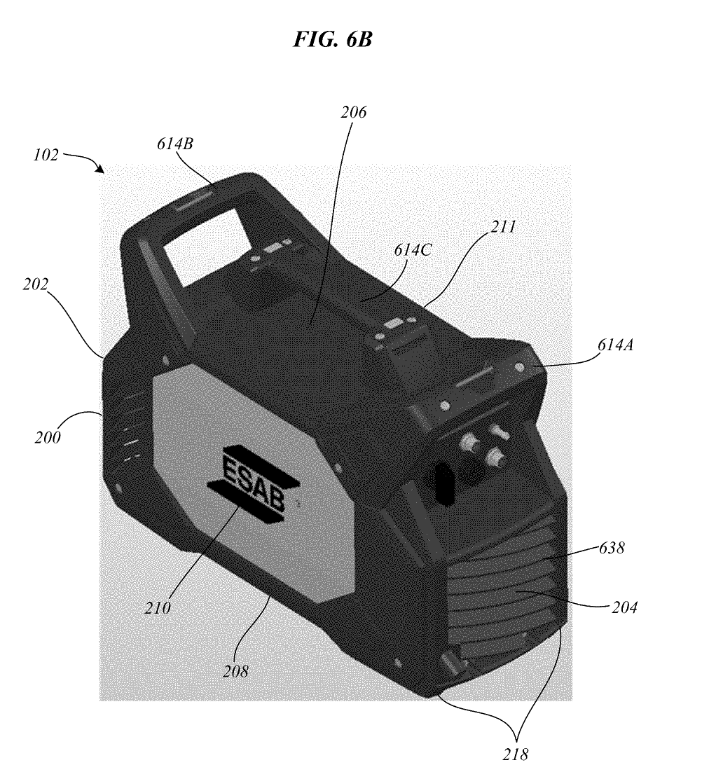

The main case 200 may have a front side 202, a back side 204, a top side 206, a bottom side 208, a right side 210, and a left side 211 (see, e.g., FIG. 6B). The bottom side 208 may include a forward mechanical attachment mechanism 212 and a rear mechanical attachment mechanism 216. The mechanical attachment mechanisms 212, 216 may be configured to couple with the modular welding components 104-1, 104-2 (see FIG. 1). The mechanical attachment mechanisms may include one or more mechanisms and/or attachment points to enable a secure connection between the apparatus 102 and a modular welding component. In some embodiments each mechanical attachment mechanism 212, 216 is configured to couple to a paired or corresponding mechanical attachment mechanism on the modular welding component 104-1 as further described below. As used herein a mechanical attachment mechanism may include one or more mechanisms and/or devices configured to form a mechanical connection. Examples of such mechanisms and/or devices may include hooks, rails, slots, latches, screws, bolts, springs, clasps, locks, straps, pins, and the like.

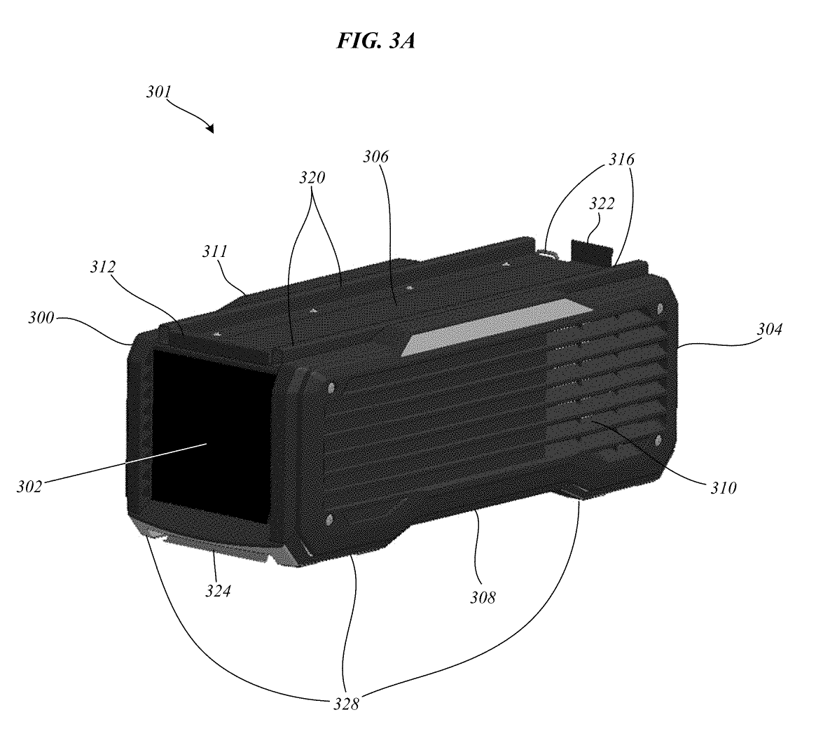

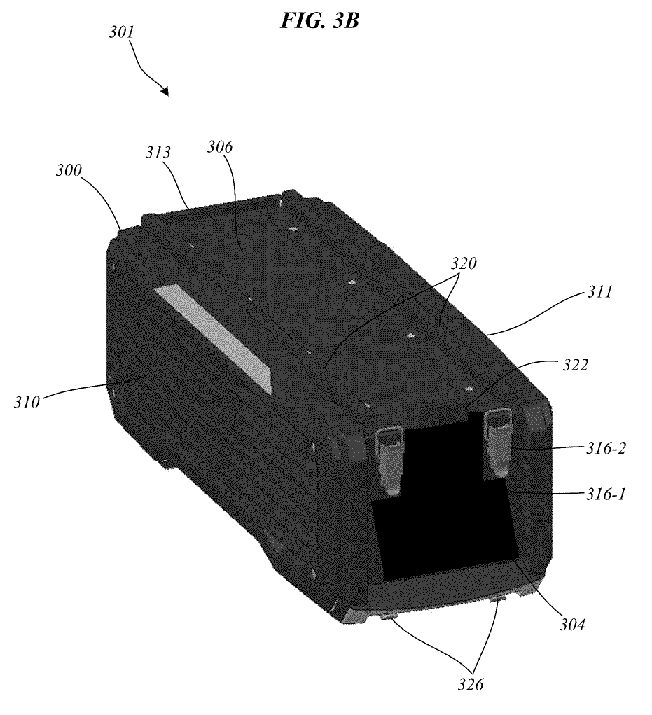

In some embodiments one of the mechanical attachment mechanisms 212, 216 may form a biased connection with a modular welding component (e.g., 104-1, 104-2), while the other mechanical attachment mechanism forms a biasing connection with the modular welding component. For example, the biasing connection may apply a force to maintain the biased connection between the apparatus 102 and the modular welding component 104-1. As shown in the illustrated embodiment, the front mechanical attachment mechanism 212 may form the biased connection and may include a forward facing hook 213 while the rear mechanical attachment mechanism 216 may form the biasing connection and may include first and second eccentric latch receptacles 216-1, 216-2. The receptacles 216-1, 216-2 may receive a latch (e.g. eccentric latches 316 shown in FIG. 3B). The latch may secure the apparatus 102 to a modular welding component (e.g., 104-1, 104-2) and prevent the forward facing hook 213 from becoming detached from the modular welding component.

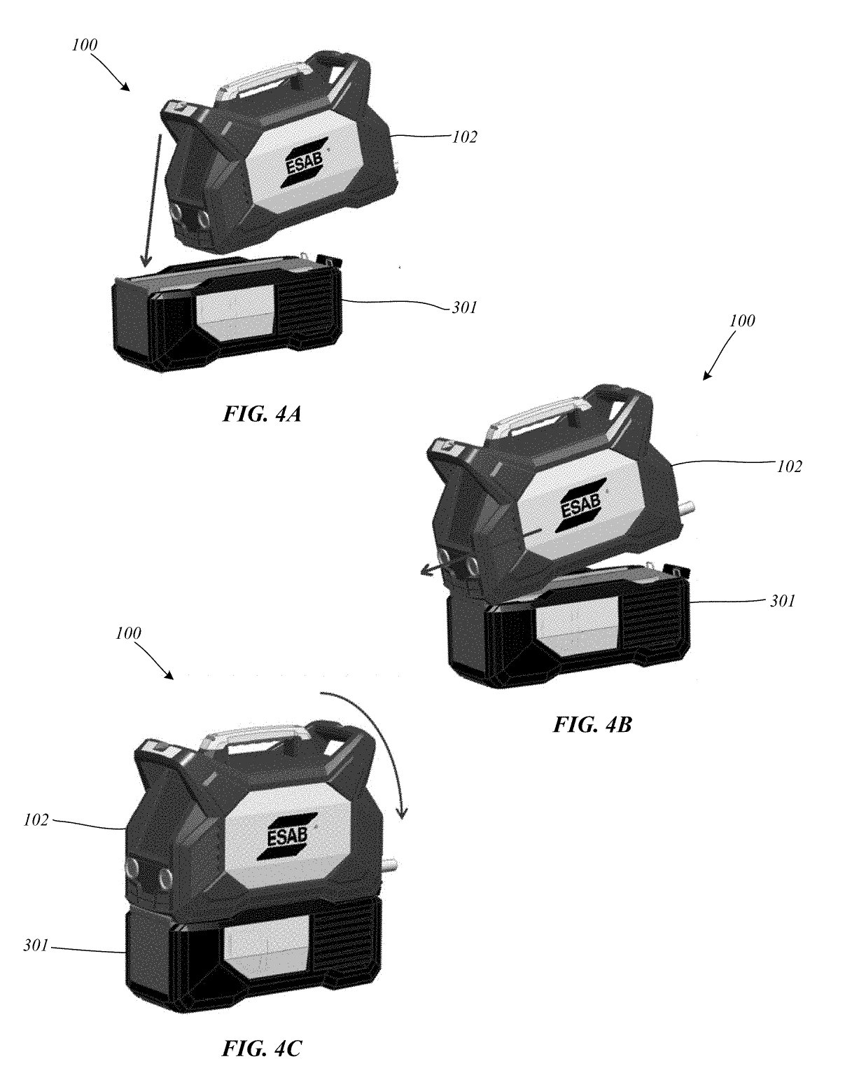

In some embodiments, the biased connection may have wider tolerances to facilitate a quick connection and the biasing connection may have narrower tolerances to facilitate a secure connection. For instance, the biased connection may only restrict movement in two dimensions while the biasing connection restricts movement in three dimensions. As will be described in more detail below with respect to FIGS. 4A-C, the biased connection, with wider tolerances, may be made first and used to align the biasing connection, which has narrower tolerances, to allow a quick and secure connection between the welding apparatus 102 and a modular welding component (e.g., 104-1, 104-2).

The welding apparatus 102 may further include feet 218. The feet 218 may allow the apparatus 102 to sit level on a surface when no modular welding components are attached to the apparatus 102. In various embodiments, the feet 218 may be configured to allow the apparatus 102 to sit atop a modular welding component (e.g., 104-1, 104-2) or another welding apparatus. In some embodiments, the feet 218 may be made of a non-conductive material to electrically isolate the apparatus 102 from whatever the apparatus 102 is sitting on.

Referring now to FIGS. 3A-B, front and rear perspective views of a modular welding component 301 consistent with non-limiting, exemplary embodiments of the present disclosure are shown. In some embodiments, the modular welding component 301 may be the same as, or similar to, the modular welding components 104-1, 104-2. The modular welding component 301 may include a component case 300. The component case 300 may enclose one or more secondary welding devices. The one or more secondary welding devices may interoperate to allow the modular welding component 301 to provide additional and/or improved welding capabilities to the apparatus 102 described above. The embodiments are not limited in this context.

The component case 300 may have a front side 302, a back side 304, a top side 306, a bottom side 308, a right side 310, and a left side 311. The top side 306 may include a top-forward mechanical attachment mechanism 312, guide rails 320, and a back plate 322. A top-rear mechanical attachment mechanism 316 may be located on the back side 304 and may extend above the top side 306. These components may allow the welding apparatus 102 to be quickly and securely coupled to modular welding component 301 and/or other non-modular welding components, such as trolley 502, as further described below.

The guide rails 320 may extend from the back plate 322 to the top-forward mechanical attachment mechanism 312. The guide rails 320 may assist with alignment when coupling the welding apparatus 102 to the modular welding component 301. As shown in FIGS. 3A-B, the rails 320 may be substantially parallel, with a first of the rails 320 extending approximately along the intersection of the right and top sides 310, 306 and with a second of the rails 320 extending approximately along the intersection of the left and top sides 311, 306. In various embodiments, the rails 320 may guide the forward mechanical attachment mechanism 212 of welding apparatus 102 (see FIG. 2) into the top-forward mechanical attachment mechanism 312 when the modular welding component 301 and apparatus 102 are being coupled. In various such embodiments the rails 320 may cooperate with the feet 218 of the apparatus 102 to align and guide the attachment points 212, 312 into engagement.

The back plate 322 may prevent the apparatus 102 from sliding off the back side 304 of the modular welding component 301. In some embodiments the back plate 322 may be attached to the back side 304 of the modular welding component 301 and may extend above the top side 306. The back plate 322 may ensure that the apparatus 102 (see FIG. 1) is correctly positioned atop the modular welding component 301 prior to securing the top-rear mechanical attachment mechanism 316.

As best shown in FIG. 3B, the top-forward mechanical attachment mechanism 312 may include a rear facing hook 313, and the top-rear mechanical attachment mechanism 316 may include eccentric latches 316-1, 316-2. In the illustrated embodiment, the rear facing hook 313 may receive the forward facing hook 213 of the welding apparatus 102 (see FIG. 2). Further, the eccentric latches 316-1, 316-2 may secure the apparatus 102 to the modular welding component 301 by latching to the eccentric latch receptacles 216-1, 216-2 of the apparatus 102. In some embodiments the latches 316-1, 316-2 may bias the forward facing hook 213 in contact with the rear facing hook 313.

Additionally, the modular welding component 301 may include bottom-forward and bottom-rear mechanical attachment mechanisms 324 (see FIG. 3A), 326 (see FIG. 3B). In various embodiments, these mechanical attachment mechanisms 324, 326 may allow additional modular welding components to be securely attached to the bottom of the modular welding apparatus 301 in a convenient manner. In various such embodiments the bottom-front attachment point 324 may be a functional equivalent of the forward mechanical attachment mechanism 212 of the apparatus 102, while the bottom-rear attachment point 326 is a functional equivalent of the rear mechanical attachment mechanism 216 of the apparatus 102.

The modular welding component 301 may also include feet (not within view) to allow the component 301 to sit level on a surface, which may be particularly useful when the component 301 is the lowermost modular welding component (e.g. the modular welding component 104-2 in FIG. 1) of the system 100. In various embodiments the feet 328 may be similar to the feet 218 of the apparatus 102 and may enable the modular welding component 301 to sit atop another modular welding component (e.g., 104-1, 104-2). In some embodiments the feet 328 may be made of a non-conductive material to electrically isolate the system 100 from whatever it is sitting on.

Referring to FIGS. 4A-C, a series of views are presented that illustrate an exemplary manner in which the apparatus 102 may be quickly and securely coupled to the modular welding component 301. It will be appreciated that the coupling may be performed with the modular welding component 301 resting on a flat surface, though this is not critical.

Referring FIG. 4A, a front-bottom corner of the welding apparatus 102 may be moved into contact with the top side 306 of the modular welding component 301. This contact may result in an acute angle being formed between the top side 306 of the modular welding component 301 and the bottom side 208 of the apparatus 102. The forward facing hook 213 (see FIG. 2) of the apparatus 102 may be positioned between the guide rails 320 (see FIG. 3) of the modular welding component 104, while the feet 218 (see FIG. 2) of the apparatus 102 are positioned on the exterior sides of the guide rails 320 (see FIG. 3) of the modular welding component 301.

Next, referring to FIG. 4B, the apparatus 102 may be slid toward the front side 302 of the modular component 301 until the forward facing hook 213 contacts the rear facing hook 313 (see FIG. 3) of the modular welding component 301. Once the apparatus 102 has been slid forward the remaining portion of the bottom side 208 of the apparatus 102 may be in position to contact the top side 306 of the modular welding component 301. In various embodiments this connections restricts movement of the apparatus 102 relative to the modular welding component 301. In various such embodiments, by restricting movement in some directions but allowing movement in another direction can assist with aligning the rear mechanical attachment mechanisms 216, 316. For example, the connection may prevent the apparatus 102 from moving further forward and/or side-to-side. However, by allowing the apparatus 102 to rotate about the top-forward mechanical attachment mechanism 312, the eccentric latch receptacles 216-1, 216-2 may be guided into position to couple with eccentric latches 316-1, 316-2.

Referring to FIG. 4C, the rear-bottom corner of the apparatus 102 may be lowered onto the top side 306 of the modular welding component 301. Positioned thusly, the apparatus 102 may be disposed between the top-forward mechanical attachment mechanism 312 and the back plate 322 (see FIG. 3) of the modular component 301. This may force the rear mechanical attachment mechanism 216 of the apparatus 102 into engagement with the top-rear mechanical attachment mechanism 316 of the modular welding component 301.

Once the apparatus 102 is positioned atop the modular welding component 301 as described above, the mechanical attachment mechanisms 216, 316 may be coupled to secure the apparatus 102 to the modular welding component 301. For example, the two eccentric latches 316-1, 316-2 (see FIG. 3) of the modular welding component 301 may be coupled to the eccentric latch receptacles 216-1, 216-2 (see FIG. 2) of the apparatus 102. In some embodiments this connection restricts movement of the apparatus 102 relative to the component 301 in three dimensions, thus allowing them to be lifted and carried as a single unit.

As may be appreciated, by including mechanical attachment mechanisms 324, 326 on the bottom of modular welding component 301 that are functional equivalents of the mechanical attachment mechanisms 212, 216 of the apparatus 102, a system 100 with multiple modular welding components 301 may be readily assembled in a convenient manner. In some embodiments, one or more of apparatus 102 and modular welding component 301 may additionally couple with non-modular welding components including accessory equipment, such as a trolley or a welding rack, in the same or a similar manner.

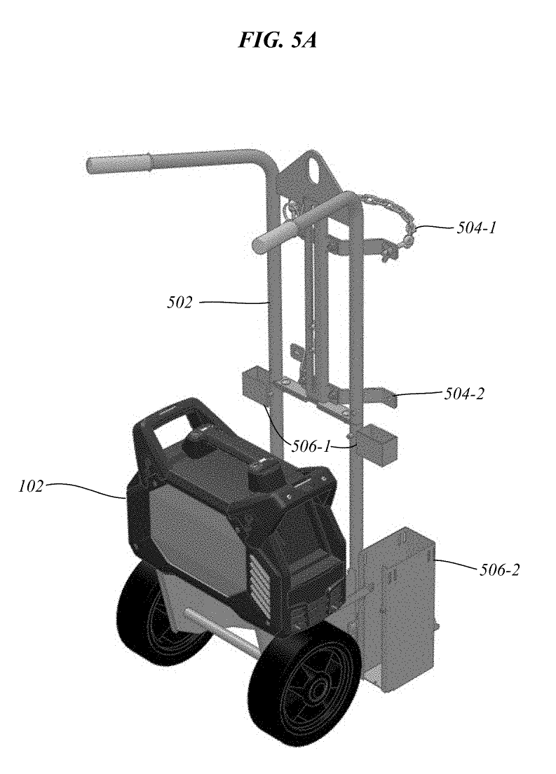

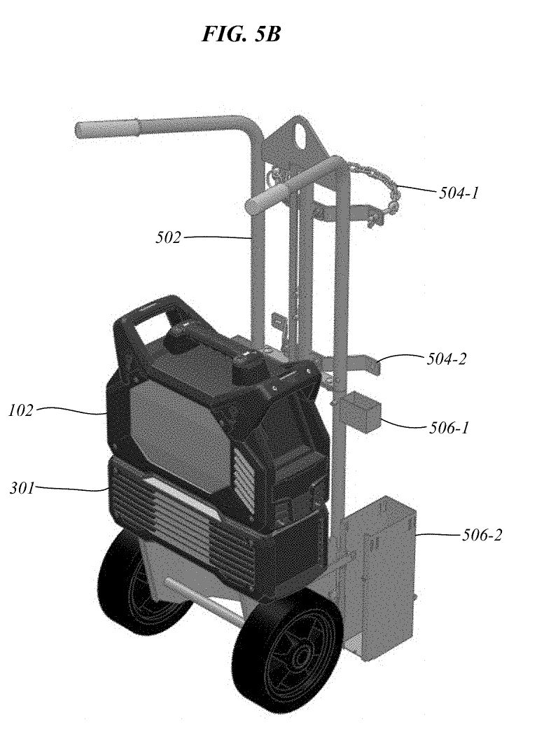

Referring now to FIGS. 5A-B, apparatus 102 or modular welding component 301 may couple with non-modular welding components. In the illustrated embodiment, trolley 502 is a non-modular welding component and may include attachment components that are the same or similar to those of top-forward mechanical attachment mechanism 312 and top-rear mechanical attachment mechanism 316. In this way, system 100 may couple with non-modular welding components, such as trolley 502 in the same or a similar manner as described with respect to FIGS. 4A-C. Coupling system 100 to non-modular welding components, such as trolley 502, may improve portability of system 100 and reduce user fatigue by providing a mechanical advantage. In the illustrated embodiment, trolley 502 may include various components to attach or hold various welding components and/or accessories, such as compressed gas tank couplers 504-1, 504-2 and welding component holders 506-1, 506-2. For example, welding component holders 506-1, 506-2 may provide storage for one or more of a welding hood, a welding apron, gloves, additional filler wire or electrodes, and similar.

Various additional features and components of the welding apparatus 102 and the modular welding components 104-1, 104-2, 301 will now be described in greater detail with respect to FIGS. 6A-9.

Referring now to FIGS. 6A-6, the case 200 may include a plurality of handle members 614A-C that may be arranged in a spaced-apart relationship about the case 200 to enable a user to conveniently grasp and lift the case 200, such as for moving the apparatus 102 to a desired location. As will be described in greater detail below, the handle members 614A-C may be positioned at specific locations about the case 200 so as to provide for ease of handling as well as for protection of one or more features of the case 200 that may be relatively fragile and susceptible to damage.

As described above, the bottom side 208 of the case 200 may include feet 218 (best shown in FIG. 2) that may extend below the mechanical attachment mechanisms 212, 216 of the apparatus 102 to provide the case 200 with stability when the case 200 is set upon an uneven surface. The feet 218 are shown in FIG. 2 as being substantially parallel, elongated rails, though it is contemplated that in various alternative embodiments the feet 218 may be implemented as any suitable structures or features that extend or project from the bottom side 208 of the case 200. In some embodiments, the feet 218 may wrap slightly around the front and back sides 202, 204 of the case 200 in a manner that provides protection for front and rear edges of the case 200.

Referring to FIG. 6A, the case 200 may include a user interface 630 that may be mounted on the front side 202 of the case 200 to enable a user to control and/or identify operational aspects and/or states of the one or more welding components within the case (e.g., primary welding devices 850 shown in FIG. 8). In some embodiments the user interface 630 may be or may include one or more of a liquid crystal display (LCD), a touchscreen, or various input devices such as buttons, knobs, switches, and the like. In the illustrated embodiment, the case 200 may be provided with bumpers 640 extending from either side of the user interface 630 for protecting the user interface 630. In some embodiments, the bumpers 630 may be integral with the case 200 (e.g., molded into the case 200), while in other embodiments the bumpers 640 may be separate components that are mechanically fastened to the case 200.

The case 200 may further include welding torch connections 632, 634 for facilitating the connection of a welding torch (not shown) and a grounding cable (not shown) to the apparatus 102. Front and rear louvers 636, 638 (rear louvre 638 is shown in FIG. 6B) may be provided in the front and back sides 202, 204 of the case 200 for allowing air to flow through the interior the case 200 to provide the apparatus 102 with cooling. In some embodiments, louvres may additionally or alternatively be provided in the right and left sides 210, 211 of the case 200.

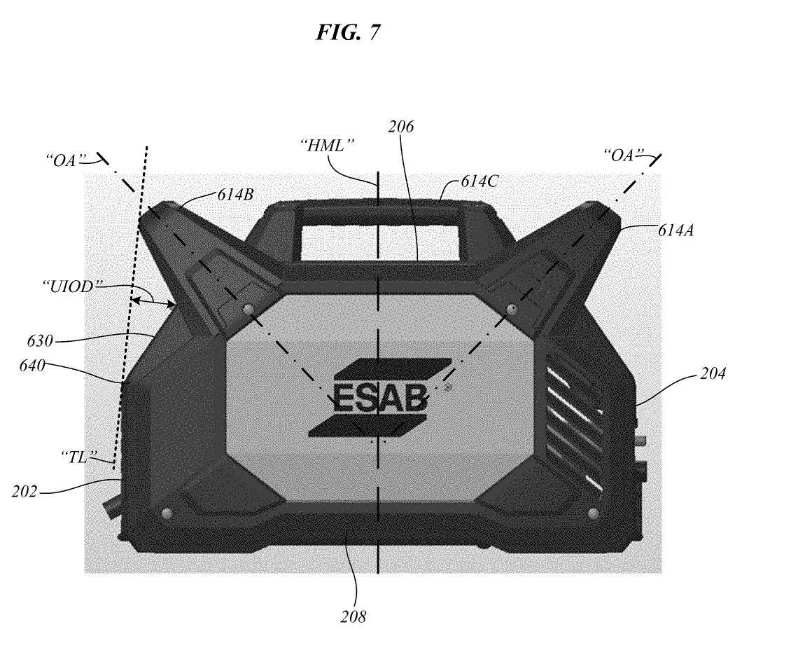

As can be seen best in FIG. 7, the handle members 614A-C are positioned about the case 200 to enable easy handling as well as to protect aspects of the case from damage. First handle member 614A may be associated with the back side 204 of the case 200, while second handle member 614B may be associated with the front side 202 of the case. A third handle member 614C may be positioned on the top side 206 of the case 200. As can be seen, the first and second handle members 614A-B are of the same design, while the third handle member 614C is an elongated design having a shape that is different from the first and second handle members. The third handle member may extend generally from the front to the back side 202, 204 of the case 200. In some embodiments one or more of the handle members 614A, 614B, 614C may facilitate the attachment of a shoulder strap or other lifting aid (not shown) to the case 200.

The first and second handle members 614A, 614B are positioned at the intersection between the back and front sides 204, 202, respectively, and the top side 206. The first and second handle members 614A, 614B may generally extend from the left to the right side 211, 210 of the case 200. The first and second handle members 614A, 614B can have an angled orientation such that a line drawn through their respective orientation axes “OA” generally intersects the horizontal midline “HML” of the case 200, thus providing a stable lifting arrangement.

As can be seen in FIG. 7, the second handle member 614B is positioned so that a line “TL” connecting tangent surfaces of the second handle member and bumper 640 of the case 200 is offset from elements of the user interface 630 by a user interface offset distance “UIOD.” As will be appreciated, this arrangement of second handle member 614B and bumper 640 can provide protection of the user interface 630 against a variety of impacts that could damage the user interface. The positioning of the second handle member 614B and the bumpers 640, as well as the angle of the user interface 630, can also result in a desired degree of shading of the user interface, which may be desired in outdoor sunlit conditions.

Referring to FIG. 8, a side cut-away view of the welding apparatus 102 is shown. The case 200 may include a plurality of drainage channels 802, 804, 806, 808, 810 formed in the sidewalls of the case 200 for directing liquids such as rain water away from the primary welding devices 850 disposed within the case 200. The primary welding devices 850 may include various devices such as a power supply, a ventilation system, electronic circuitry, etc., some or all of which may be susceptible to damage and/or corrosion if exposed to liquids. Further, exposure of primary welding devices 850 to liquids can cause safety issues, such as a risk of electrical shock to a user, for instance.

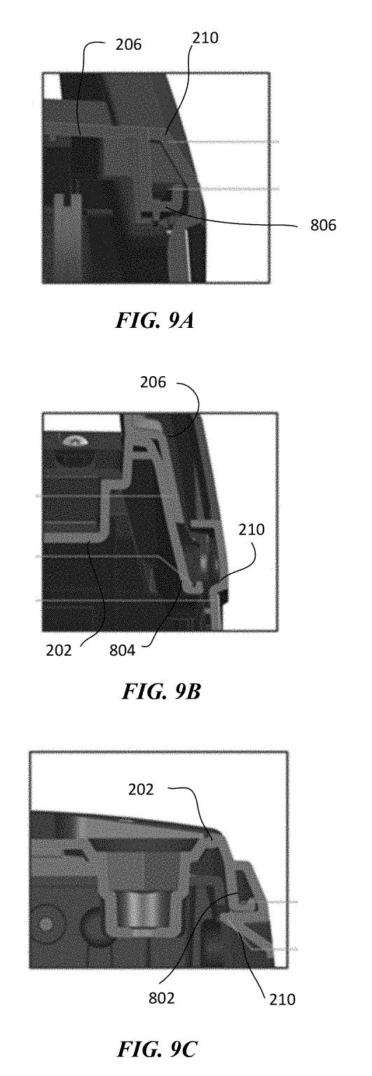

FIGS. 9A-9C illustrate respective cross sectional views of the case 200 taken along planes A-A, B-B, and C-C from FIG. 8. Specifically, FIG. 9A depicts a junction between the top side 206 and the right side 210 of the case 200. The top side 206 may include drainage channel 806, which may be covered by the right side 210 of the case 200. The top and right sides 206, 210 of the case may adjoin one another above the drainage channel 806 such that liquids flowing into the case 200 at the juncture of the right and top sides 210, 206 will be directed into the drainage channel 806. The embodiments are not limited in this context.

FIG. 9B depicts a junction between the front, right, and top sides 202, 240, 206 of the case 200. The top side 206 may overlap with the front side 202. The front side 202 may include drainage channel 804 overlapped and covered by the right side 210. The front and right sides 202, 210 may contact each other above the drainage channel 804 such that liquids flowing into the case 200 at the juncture of the front and rights sides 202, 210 will be directed into the drainage channel 804. In some embodiments, liquids from drainage channel 806 may also be directed into drainage channel 804. The drainage channel 808 (see FIG. 8) located on the opposite side of the case relative to the drainage channel 804 may be substantially identical to the drainage channel 804.

FIG. 9C depicts a junction between the front side 202 and the right side 210 of the case 200. The right side 210 may overlap with the front side 202. The front side 202 may include the drainage channel 802 overlapped by right side 210. The front side 202 and the right side 210 may adjoin one another above the drainage channel 804 such that liquids flowing into the case at the juncture of the front and right sides 202, 210 will be directed into the drainage channel 802. In some embodiments, liquids from drainage channel 804 may be directed into drainage channel 802. The drainage channel 810 (see FIG. 8) located on the opposite side of the case relative to the drainage channel 802 may be substantially identical to the drainage channel 804.

In various embodiments the above-described drainage channels 802-810 may prevent liquids from accumulating on the top side 206 of the apparatus 102 and entering the case 200. In certain embodiments, the drainage channels 802-810 may prevent liquids from flowing over the user interface 630 and/or the welding torch connections 632, 634. It is contemplated that the specific configuration and arrangement of the drainage channels 802-810 described above may be varied for protecting various components of the apparatus without departing from the present disclosure. For example, a set of drainage channels that are substantially identical to the drainage channels 802-810 may additionally or alternatively be implemented on the left side 211 of the apparatus 102.

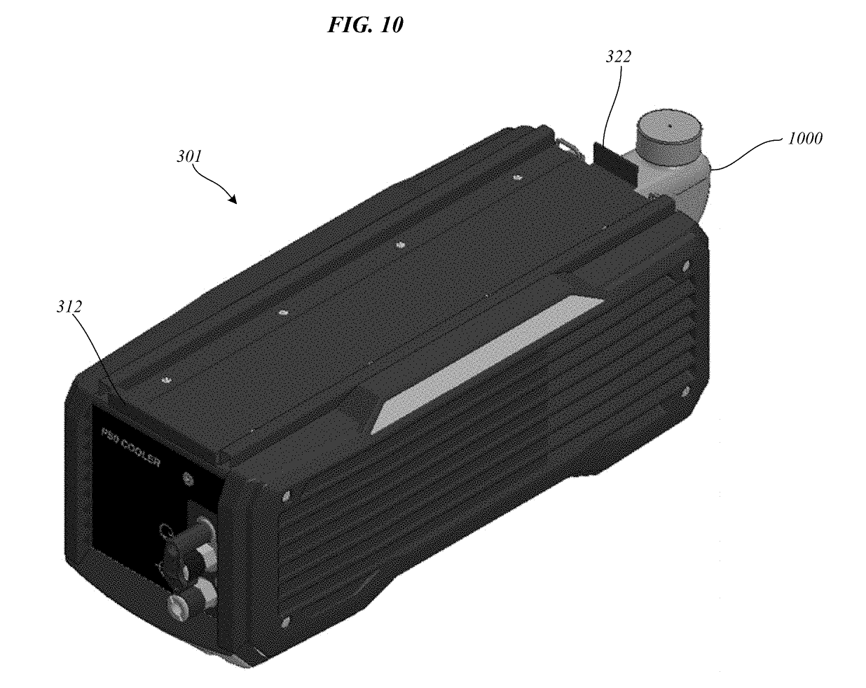

Referring to FIG. 10, a perspective of the above-described modular welding component 301 is shown. In an exemplary embodiment, the modular welding component 301 may be a coolant supply that may house a reservoir 1000 of coolant. As described above, the modular welding supply 301 may be provided with mechanical attachment mechanisms 312, 322 that may facilitate coupling of the modular welding component 301 to the apparatus 102. In various embodiments, the modular welding component 301 may include a pump and one or more external fluid lines (not shown) for circulating a coolant from the reservoir 1000 through the apparatus 102 for cooling various components of the apparatus 102. The embodiments are not limited in this context.

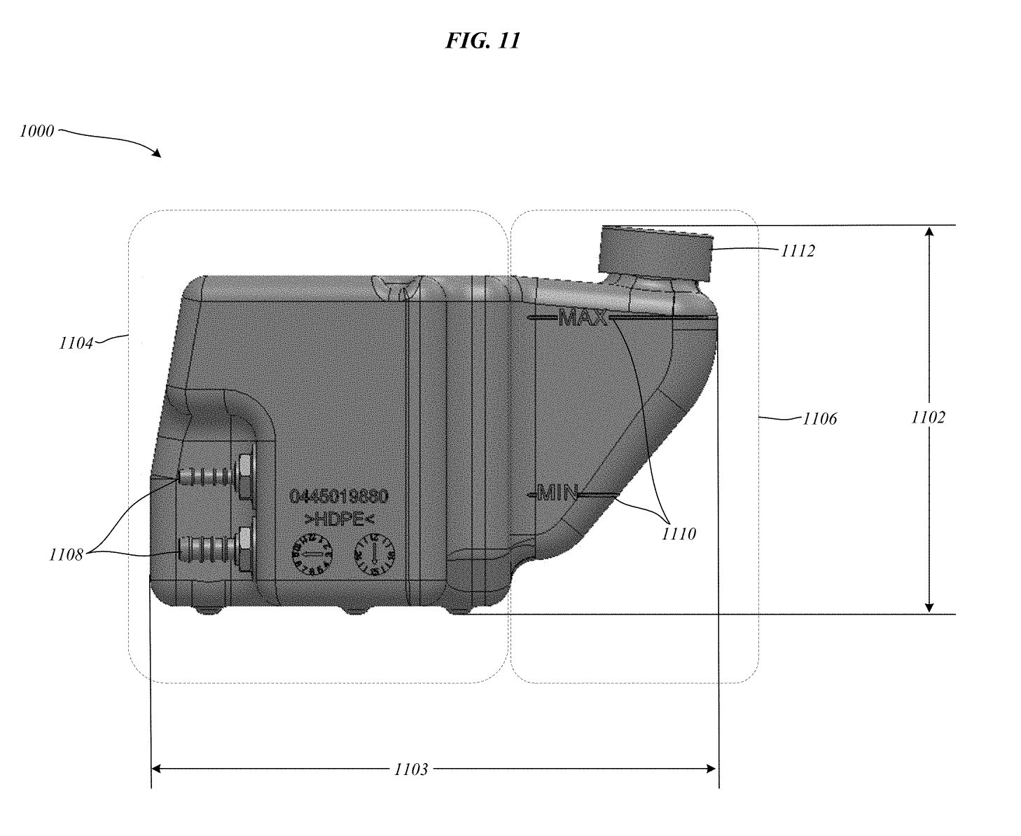

Referring to FIG. 11, a detailed side view of the reservoir 1000 is shown. The reservoir 1000 may include a body portion 1104 and a neck portion 1106. Reservoir 1000 may have height 1102 and width 1103. The body portion 1104 may be substantially enclosed by the modular welding component 301 (see FIG. 10) and the neck portion 1106 may protrude from the modular welding component 301.

The body portion 1104 of the reservoir 1000 may include fluid ports 1108. The fluid ports 1108 may be connected in fluid communication with a pump (not shown) of the modular welding component 104, such as via fluid lines (not shown) for circulating coolant through the reservoir 1000 and the welding apparatus 102 as described above. In various embodiments body portion 1104 can have approximately the same height 1102 as reservoir 1000.

The neck portion 1106 of the reservoir 1000 may be configured to receive coolant from an external source for storage in the reservoir 1000. For example, the neck portion 1106 may have a resealable fluid inlet 1112 provided with a screw or twist cap. In some embodiments, neck portion 1106 may approximately extend the entire height 1102 and/or depth of reservoir 1000. Extending approximately the entire height 1102 of reservoir 1000 can result in a more robust connection between body portion 1104 and neck portion 1106. For example, as neck portion 1106 may protrude from modular welding component 301, a more robust connection between body portion 1104 and neck portion 1106 may prevent neck portion 1106 from breaking off of reservoir 1000. Additionally, extending approximately the entire height 1102 and depth of reservoir 1000 can provide additional capacity for reservoir 1000. In the illustrated embodiment, neck portion 1106 can increase the capacity of reservoir 1000 without increasing the width 1103 of reservoir 1000. In various embodiments, the neck portion 1106 may be translucent and may include fluid level indicia 1110 (e.g., min and max fill levels) that may allow a user to visually determine an amount of coolant in the reservoir 1000.

In various embodiments, resealable fluid inlet 1112 may be approximately parallel with the top of reservoir 1000. With resealable fluid inlet 1112 arranged approximately parallel with the top of reservoir 1000 and neck portion 1106 extending approximately the height 1102 and depth of reservoir 1000, easier filling and less spilling of cooling fluid may be achieved. For example, a funnel used for filling reservoir 1000 may be inserted further into resealable fluid inlet 1112 to prevent the funnel from falling out of reservoir 1000 during filling.

The features described herein may enable the welding system 100 to operate with improved flexibility. For example, the one or more modular welding components included in the system 100 may be customized and/or optimized for a specific welding operation. Further, the modular design of the system 100 can simplify relocation of the system 100 from site to site. Additionally, the cases of the apparatus 102 and the modular welding components 104-1, 104-2, 301 may improve maintenance intervals and/or the lifespan of the system 100, thereby increasing efficiency of the system 100.

As used herein, an element or operation recited in the singular and proceeded with the word “a” or “an” should be understood as not excluding plural elements or operations, unless such exclusion is explicitly recited. Furthermore, references to “one embodiment” of the present disclosure are not intended to be interpreted as excluding the existence of additional embodiments that also incorporate the recited features.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A portable welding apparatus comprising:
a main case housing a primary welding device that facilitates a welding function of the portable welding apparatus, the main case having a mechanical attachment mechanism on a bottom surface thereof for facilitating coupling of the portable welding apparatus to a component case of a modular welding component housing a secondary welding device that supplements the primary welding device.

2. The portable welding apparatus of claim 1, wherein the mechanical attachment mechanism comprises a first mechanical attachment mechanism disposed adjacent a first side of the main case and a second mechanical attachment mechanism disposed adjacent a second side of the main case opposite the first side.

3. The portable welding apparatus of claim 2, wherein the first mechanical attachment mechanism is adapted to form a biased connection with the component case and wherein the second mechanical attachment mechanism is adapted to form a biasing connection with the component case.

4. The portable welding apparatus of claim 2, wherein the first mechanical attachment mechanism is a hook and the second mechanical attachment mechanism includes a latch.

5. The portable welding apparatus of claim 1, the mechanical attachment mechanism for facilitating coupling of the portable welding apparatus to a non-modular welding component.

6. The portable welding apparatus of claim 5, the non-modular welding component comprising a trolley.

7. The portable welding apparatus of claim 1, further comprising a drainage channel formed in a sidewall of the main case, the drainage channel configured to direct fluid that enters a top of the main case around the primary welding device and out of the main case without allowing the fluid to come into contact with the primary welding component.

8. The portable welding apparatus of claim 1, further comprising an integral user interface associated with the primary welding component, and a bumper extending from the main case adjacent the user interface for protecting the user interface.

9. The portable welding apparatus of claim 1, further comprising a first handle disposed adjacent a first side of the main case, a second handle disposed adjacent a second side of the main case opposite the first side, the first handle and the second handle parallel with one another, and a third handle disposed intermediate the first handle and the second handle, the third handle perpendicular to the first handle and the second handle.

10. A welding system comprising:
a portable welding apparatus comprising a main case housing a primary welding device that facilitates a welding function of the portable welding apparatus; and
a modular welding component removeably attached to a bottom of the portable welding apparatus, the modular welding component comprising a component case housing a secondary welding device that supplements the primary welding device.

11. The welding system of claim 10, wherein the main case is provided with a mechanical attachment mechanism on a bottom surface thereof for facilitating removable coupling of the portable welding apparatus to the modular welding component.

12. The welding system of claim 11, wherein the mechanical attachment mechanism of the main case comprises a first mechanical attachment mechanism disposed adjacent a first side of the main case and a second mechanical attachment mechanism disposed adjacent a second side of the main case opposite the first side.

13. The welding system of claim 12, wherein the first mechanical attachment mechanism is adapted to form a biased connection with the component case of the modular welding component and wherein the second mechanical attachment mechanism is adapted to form a biasing connection with the component case of the modular welding component.

14. The welding system of claim 13, wherein the biased connection restricts relative movement of the portable welding apparatus and the modular welding component in two dimensions and wherein the biasing connection restricts relative movement of the portable welding apparatus and the modular welding component in three dimensions.

15. The welding system of claim 12, wherein the first mechanical attachment mechanism is a hook and the second mechanical attachment mechanism includes a latch.

16. The welding system of claim 12, further comprising feet extending from the bottom surface of the main case beyond the mechanical attachment mechanism of the main case for allowing the portable welding apparatus to be disposed on a surface without the mechanical attachment mechanism of the main case touching the surface.

17. The welding system of claim 10, wherein the component case is provided with a mechanical attachment mechanism on a bottom surface thereof for facilitating removable coupling of the modular welding component to another modular welding component.

18. The welding system of claim 10, further comprising a drainage channel formed in a sidewall of the main case, the drainage channel configured to direct fluid that enters a top of the main case around the primary welding device and out of the main case without the allowing the fluid to come into contact with the primary welding component.

19. The welding system of claim 10, wherein the portable welding apparatus is provided with an integral user interface associated with the primary welding component, and wherein a bumper extends from the main case adjacent the user interface for protecting the user interface.

20. The welding system of claim 10, further comprising a first handle disposed adjacent a first side of the main case, a second handle disposed adjacent a second side of the main case opposite the first side, the first handle and the second handle parallel with one another, and a third handle disposed intermediate the first handle and the second handle, the third handle perpendicular to the first handle and the second handle.
